(19) United States
(12) Patent Application Publication
(10) Pub. No.: US 2026/0305444 A1
(43) Pub. Date: Oct. 1, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Keiji BEPPU, Tokyo (JP); Naoto KANO, Tokyo (JP)

(73) Assignee: Mitsubishi Electric Corporation, Tokyo (JP)

(21) Appl. No.: 19/439,090

(22) Filed: Jan. 2, 2026

(30) Foreign Application Priority Data
Mar. 28, 2025 (JP) 2025-055473

(51) Int. Cl. H10W 72/90; H10W 72/00; H10W 74/01; H10W 74/10; H10W 90/00

(52) U.S. Cl. CPC H10W 72/932; H10W 72/01961; H10W 72/951; H10W 74/01; H10W 74/114; H10W 90/726

(57) ABSTRACT

A semiconductor device according to the present disclosure includes: a surface electrode solder bonding portion, wherein the surface electrode solder bonding portion includes a modified portion with an outermost surface oxidized, roughened and a solder bonding region, the modified portion includes a plurality of processing regions disposed to surround an outer surrounding portion of the solder bonding region, each of the processing regions is made up of a first processing region and a second processing region surrounding an outer surrounding portion of the first processing region, and in two of the processing regions adjacent to each other, the first processing region in one of the processing regions and the first processing region in another one of the processing regions are not overlapped with each other, and the first processing region in one of the processing regions and the second processing region in another one of the processing regions are not overlapped with each other.

### BACKGROUND

### Technical Field

The present disclosure relates to a semiconductor device and a method of manufacturing a semiconductor device.

### Description of the Background Art

Known as a power semiconductor device used for an inverter, for example, is a power semiconductor device having a structure that a front surface electrode of a semiconductor element is bonded to an external electrode by solder. When such a power semiconductor device receives thermal stress of a power cycle (P/C) or a thermal cycle (T/C), for example, thermal stress caused by a linear expansion coefficient difference of each material occurs. A material interface is detached on an outermost surrounding portion of the front surface electrode by this thermal stress, and when the detachment proceeds, a problem such as cracking of a front surface electrode of the semiconductor element occurs. The cracking of the front surface electrode may occur when solder reaches an outer surrounding end portion of the front surface electrode.

Disclosed conventionally as measures against such a problem is a technique of modifying an outermost surface of an outer surrounding portion of a front surface electrode by laser irradiation (for example, refer to International Publication No. 2023/242953).

### SUMMARY

When the laser irradiation is performed, a region deeper than an unprocessed surface and a region protruding more than the unprocessed surface are formed on a surface of the front surface electrode. When the same position is repetitively irradiated with laser light, the region deeper than the unprocessed surface is further deepened, and there is a possibility that the semiconductor element is resultingly broken.

Since International Publication No. 2023/242953 does not mention that there is a possibility that the semiconductor element is broken when the same position is repetitively irradiated with laser light, there is room for improvement in stably manufacturing a semiconductor device.

The present disclosure is to solve such a problem, and an object is to provide a semiconductor device capable of being stably manufactured and a method of manufacturing the semiconductor device.

A semiconductor device according to the present disclosure includes: a semiconductor element; a surface electrode solder bonding portion provided to a front surface of the semiconductor element; a solder provided to the surface electrode solder bonding portion; and a sealing material sealing the semiconductor element and the solder, wherein the surface electrode solder bonding portion includes a modified portion with an outermost surface oxidized, roughened, and covered by the sealing material and a solder bonding region in which the solder is bonded, the modified portion includes a plurality of processing regions disposed to surround an outer surrounding portion of the solder bonding region, each of the processing regions is made up of a first processing region and a second processing region surrounding an outer surrounding portion of the first processing region, and in two of the processing regions adjacent to each other, the first processing region in one of the processing regions and the first processing region in another one of the processing regions are not overlapped with each other, and the first processing region in one of the processing regions and the second processing region in another one of the processing regions are not overlapped with each other.

According to the present disclosure, the semiconductor device can be stably manufactured.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view illustrating a configuration of a semiconductor device according to an embodiment 1.

FIG. 2 is a plan view illustrating a surface electrode solder bonding portion according to the embodiment 1.

FIG. 3 is a plan view illustrating an arrangement of a processing region according to the embodiment 1.

FIG. 4 is a diagram illustrating the processing region according to the embodiment 1.

FIG. 5 is an enlarged view illustrating an arrangement of the processing region according to the embodiment 1.

FIG. 6 is a flow chart illustrating a method of manufacturing the semiconductor device according to the embodiment 1.

FIG. 7 is a plan view illustrating an arrangement of a processing region according to an embodiment 2.

FIG. 8 is a plan view illustrating an arrangement of the processing region according to the embodiment 2.

FIG. 9 is a plan view illustrating an arrangement of a processing region according to a modification example of the embodiment 2.

FIG. 10 is a plan view illustrating an arrangement of a processing region according to a modification example of the embodiment 2.

FIG. 11 is a plan view illustrating an arrangement of a processing region according to an embodiment 3.

FIG. 12 is a plan view illustrating an arrangement of a processing region according to an embodiment 4.

FIG. 13 is a plan view illustrating an arrangement of a processing region according to a modification example of the embodiment 4.

FIG. 14 is a plan view illustrating an arrangement of a processing region according to an embodiment 5.

### DESCRIPTION OF THE PREFERRED EMBODIMENTS

### Embodiment 1

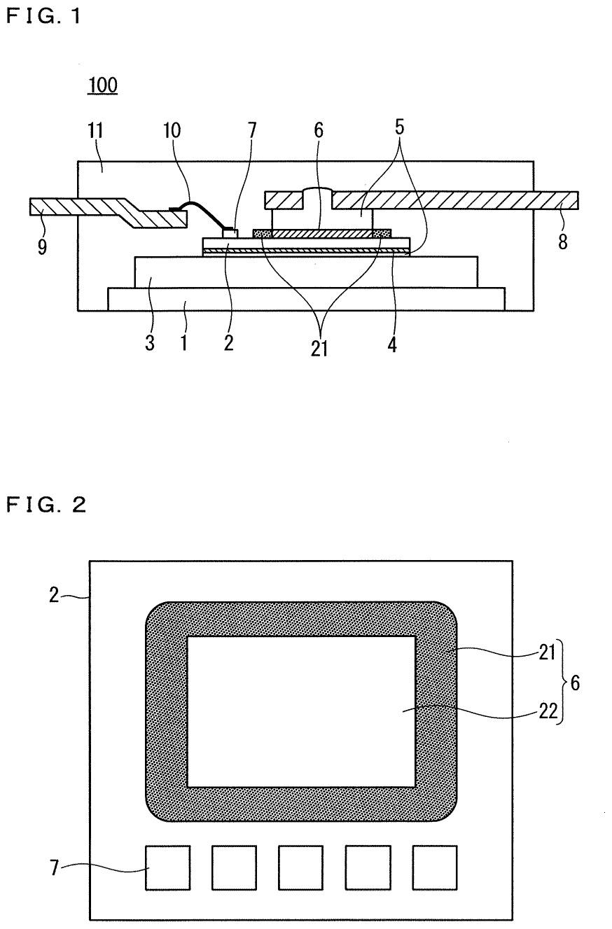

FIG. 1 is a cross-sectional view illustrating a configuration of a semiconductor device 100 according to an embodiment 1. The semiconductor device 100 includes a semiconductor element 2. The semiconductor element 2 includes a back surface electrode 4 on a back surface. The back surface electrode 4 is formed of a metal film, and is connected to a base plate 3 having a heat radiation action, using a solder 5. The base plate 3 is formed of metal such as copper (Cu), and is connected to an insulating film 1.

The semiconductor element 2 includes a surface electrode solder bonding portion 6 on a front surface. The surface electrode solder bonding portion 6 is an electrode formed of a metal film and conducting main current of the semiconductor element 2. The surface electrode solder bonding portion 6 is connected to a first external electrode 8 formed of metal such as Cu, using the solder 5.

The semiconductor element 2 includes a surface electrode wire pad portion 7 on the front surface. The surface electrode wire pad portion 7 is formed of a metal film, and is used for driving and controlling the semiconductor element 2. The surface electrode wire pad portion 7 is connected to a second external electrode 9 electrically separated from the surface electrode solder bonding portion 6, using a conductive wiring material 10 such as an aluminum wire.

The semiconductor device 100 is wholly sealed by the sealing material 11 to ensure electrical insulation and environmental resistance, for example. The sealing material 11 is formed of an insulating material made of epoxy resin, for example. An end portion of each of the first external electrode 8 and the second external electrode 9 is exposed from the sealing material 11.

FIG. 2 is a plan view illustrating the surface electrode solder bonding portion 6 according to the embodiment 1. The surface electrode solder bonding portion 6 includes a modified portion 21 with an outermost surface oxidized and roughened and a solder bonding region 22. The modified portion 21 is covered by the sealing material 11, and the solder 5 is bonded to the solder bonding region 22 (refer to FIG. 1).

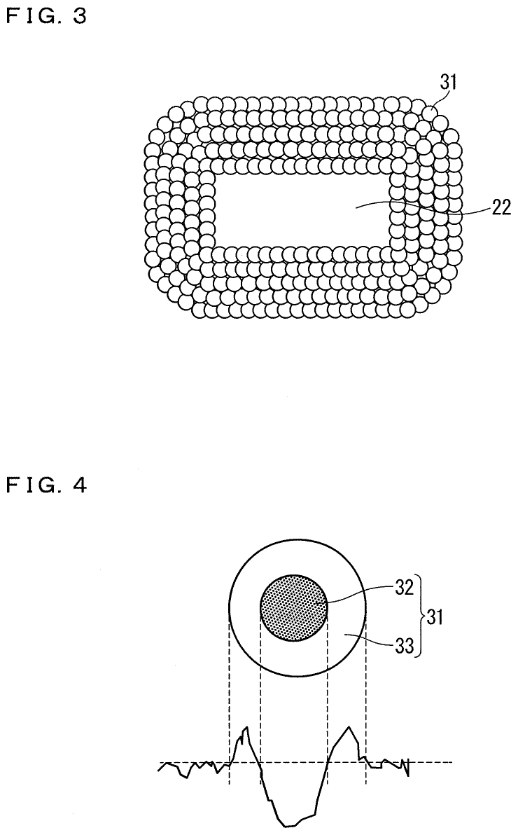

FIG. 3 is a plan view illustrating an arrangement of a processing region 31 according to the embodiment 1. The modified portion 21 includes a plurality of processing regions 31 disposed to surround an outer surrounding portion of the solder bonding region 22. The modified portion 21 is formed by pulse irradiation with laser light. One processing region 31 is a region processed by a single shot of pulse irradiation with the laser light. Described in the present disclosure is a case where the modified portion 21 is formed by pulse irradiation with the laser light. However, the modified portion 21 may be formed by the other method.

FIG. 4 is a diagram illustrating the processing region 31. An upper diagram in FIG. 4 illustrates a plan view of the processing region 31, and a lower diagram in FIG. 4 illustrates a cross-sectional view of the processing region 31. A broken line in a lateral direction illustrated in the lower diagram in FIG. 4 illustrates a reference surface of the processing region 31 in a height direction, and corresponds to a surface of the solder bonding region 22.

The processing region 31 is made up of a first processing region 32 and a second processing region 33 surrounding an outer surrounding portion of the first processing region 32. The first processing region 32 has a concave shape concaved more than the reference surface. The second processing region 33 has a convex shape protruding more than the reference surface. The first processing region 32 and the second processing region 33 are formed by a single shot of pulse irradiation with the laser light. A shape of the processing region 31 is not limited to a precise circular shape, but may also be an oval shape.

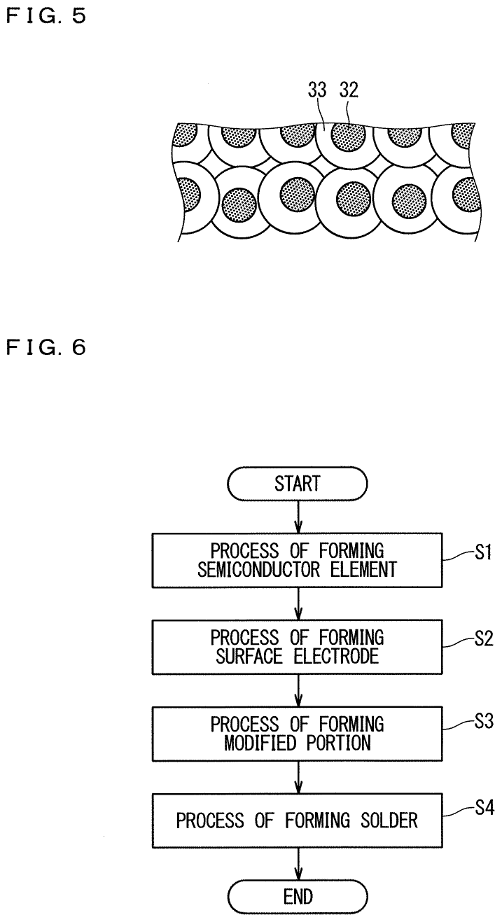

FIG. 5 is an enlarged view illustrating an arrangement of the processing region 31. In two processing regions 31 adjacent to each other, the first processing region 32 in one of the processing regions 31 and the first processing region 32 in the other one of the processing regions 31 are not overlapped with each other. The first processing region 32 in one of the processing regions 31 and the second processing region 33 in the other one of the processing regions 31 are not overlapped with each other.

FIG. 6 is a flow chart illustrating a method of manufacturing the semiconductor device according to the embodiment 1.

In Step S1, the semiconductor element 2 is formed. Examples of the semiconductor element 2 include an insulated gate bipolar transistor (IGBT) or a metal oxide semiconductor field effect transistor (MOSFET).

In Step S2, the front surface electrode is formed on the front surface of the semiconductor element 2. Specifically, the surface electrode solder bonding portion 6 and the surface electrode wire pad portion 7 made up of a metal film are formed on the front surface of the semiconductor element 2.

In Step S3, the modified portion 21 is formed in the surface electrode solder bonding portion 6. Specifically, pulse irradiation with the laser light is performed in a region (a region forming the modified portion 21) surrounding an outer surrounding portion of the solder bonding region 22. As described above, one processing region 31 is formed by a single shot of pulse irradiation. Thus, the modified portion 21 is formed by performing pulse irradiation several times.

In the modified portion 21, in two processing regions 31 adjacent to each other, the first processing region 32 in one of the processing regions 31 and the first processing region 32 in the other one of the processing regions 31 are not overlapped with each other, and the first processing region 32 in one of the processing regions 31 and the second processing region 33 in the other one of the processing regions 31 are not overlapped with each other. Thus, when the first processing region 32 is not crushed but is firmly left in a case of seeing the modified portion 21, the modified portion 21 is deemed to be formed using the manufacturing method according to the present disclosure.

In Step S4, the solder 5 is formed on the solder bonding region 22, and the surface electrode solder bonding portion 6 and the first external electrode 8 are electrically connected. At this time, the outermost surface of the metal film is oxidized in the modified portion 21. Thus, reaction between the solder 5 and the metal film is suppressed. Accordingly, leakage and spread of the solder 5 can be suppressed. Since the outermost surface of the metal film is roughened in the modified portion 21, a contact area between the solder 5 and the metal film increases, and a surface tension at an interface between the solder 5 and the metal film increases. Accordingly, leakage and spread of the solder 5 can be further suppressed.

Subsequently, the semiconductor element 2, for example, is sealed by the sealing material 11, and the semiconductor device 100 illustrated in FIG. 1 is completed. At this time, the modified portion 21 is covered by the sealing material 11. Since the outermost surface of the metal film is roughened in the modified portion 21, adhesive strength at an interface between the modified portion 21 and the sealing material 11 is improved.

Although the description of a process of forming the back surface electrode 4, a process of placing the semiconductor element 2 on the base plate 3, and a process of electrically connecting the surface electrode wire pad portion 7 and the second external electrode 9 using the conductive wiring material 10 is omitted in the above description, it is sufficient that these processes are performed at an optional timing in FIG. 6.

### Effect

According to the embodiment 1, in two processing regions 31 adjacent to each other, the first processing region 32 in one of the processing regions 31 and the first processing region 32 in the other one of the processing regions 31 are not overlapped with each other, and the first processing region 32 in one of the processing regions 31 and the second processing region 33 in the other one of the processing regions 31 are not overlapped with each other. Accordingly, the first processing region 32 can be prevented from being excessively deepened by repetitive irradiation of the same position with the laser light, and the semiconductor device can be stably manufactured.

### Embodiment 2

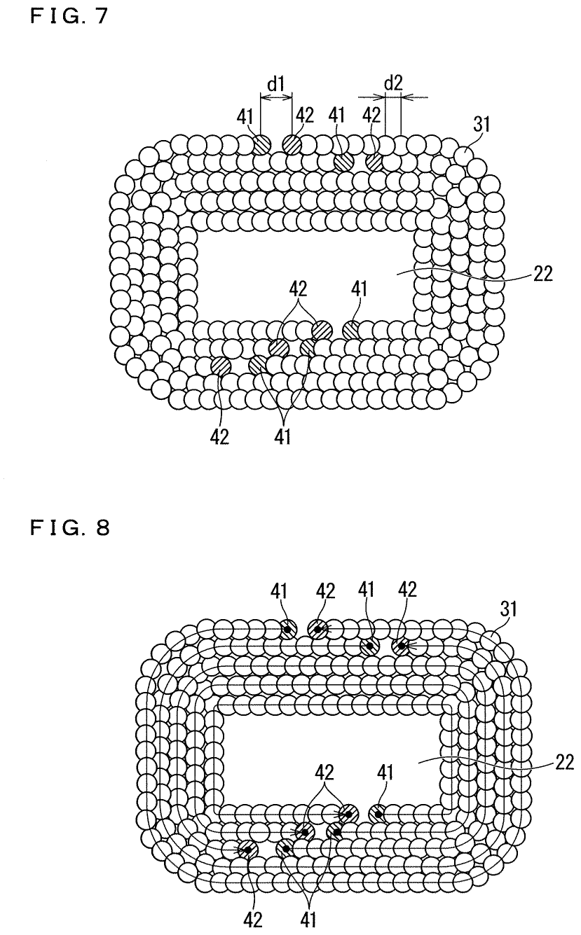

FIGS. 7 and 8 are plan views illustrating an arrangement of the processing region 3 according to the embodiment 2. As illustrated in FIGS. 7 and 8, the modified portion 21 includes a start point processing region 41 as a start point of processing and a terminal point processing region 42 as a terminal point of processing. An arrangement relationship between two processing regions 31 adjacent to each other is similar to that in the embodiment 1.

The start point processing region 41 and the terminal point processing region 42 are parts of the processing region 31, and are not overlapped with each other. An interval d1 between the start point processing region 41 and the terminal point processing region 42 is larger than an interval d2 between the processing regions 31 other than the start point processing region 41 and the terminal point processing region 42.

When the irradiation with the laser light is performed to form the processing region 31, the processing region 31 is formed so that the start point processing region 41 and the terminal point processing region 42 form one annular group as illustrated in FIG. 8. Although five groups of annular processing regions 31 are formed in the example in FIG. 8, the number of the annular groups is not limited thereto.

The processing regions 31 are formed in anticlockwise order in the example in FIG. 8, but may be formed in clockwise order. In this case, each position of the start point processing region 41 and the terminal point processing region 42 is switched.

In FIG. 8, the processing region 31 may be formed from the inner annular group, o may also be formed from the outer annular group.

In the annular go-around in FIGS. 7 and 8, the start point processing region 41 and the terminal point processing region 42 are not overlapped with each other. However, the start point processing region 41 may be overlapped with the terminal point processing region 42 in the other adjacent go-around. In the similar manner, the terminal point processing region 42 may be overlapped with the start point processing region 41 in the other adjacent go-around.

### Effect

When the interval d1 between the start point processing region 41 and the terminal point processing region 42 is the same as the interval d2 between the processing regions 31, it is necessary to set conditions such as a scanning speed of laser irradiation and a dimension of a drawing pattern (the annular group in FIG. 8) of laser irradiation so that the first processing region 32 in the start point processing region 41 and the first processing region 32 in the terminal point processing region 42 are not overlapped with each other.

According to the embodiment 2, the interval d1 between the start point processing region 41 and the terminal point processing region 42 is larger than the interval d2 between the processing regions 31 other than the start point processing region 41 and the terminal point processing region 42. Thus, it is unnecessary to set the above conditions where a scanning speed of laser irradiation is made constant and an irradiation cycle of pulse is made constant, for example. Accordingly, complication and increase of time of the process of forming the modified portion 21 can be prevented.

### Modification Example of Embodiment 2

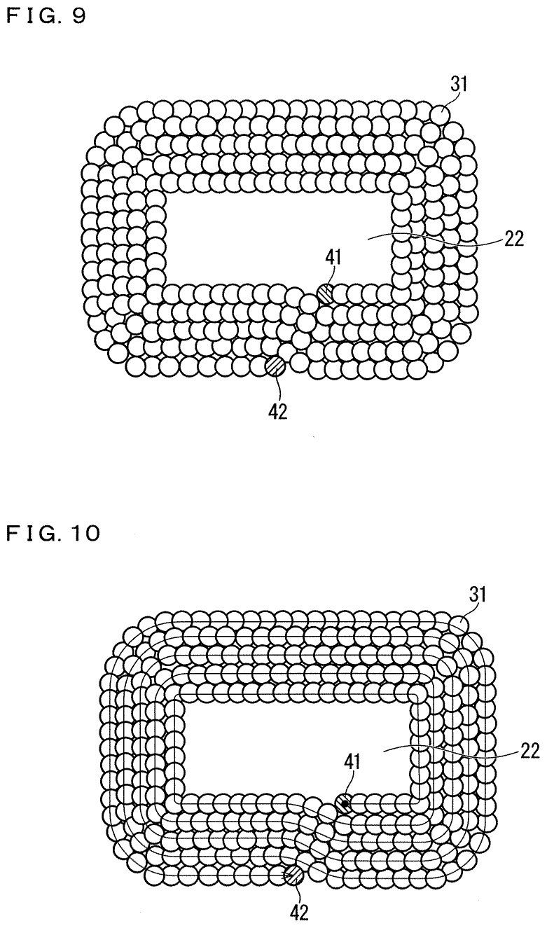

FIGS. 9 and 10 are plan views illustrating an arrangement of the processing region 31 according to a modification example of the embodiment 2. As illustrated in FIGS. 9 and 10, there are only one start point processing region 41 and one terminal point processing region 42. An arrangement relationship between two processing regions 31 adjacent to each other is similar to that in the embodiment 1.

When the irradiation with the laser light is performed to form the processing region 31, the processing region 31 is formed into a spiral form from the start point processing region 41 to the terminal point processing region 42 as illustrated in FIG. 10.

The processing region 31 is formed in anticlockwise order in the example in FIG. 10, but may be formed in clockwise order.

The processing region 31 is formed from inside in the example in FIG. 10, but may be formed from outside.

### Effect

According to the modification example of the embodiment 2, one start point processing region 41 and one terminal point processing region 42 are provided. Thus, the number of exciting states and stopping states of laser light can be reduced, and a time required for entering the exciting state can be reduced.

### Embodiment 3

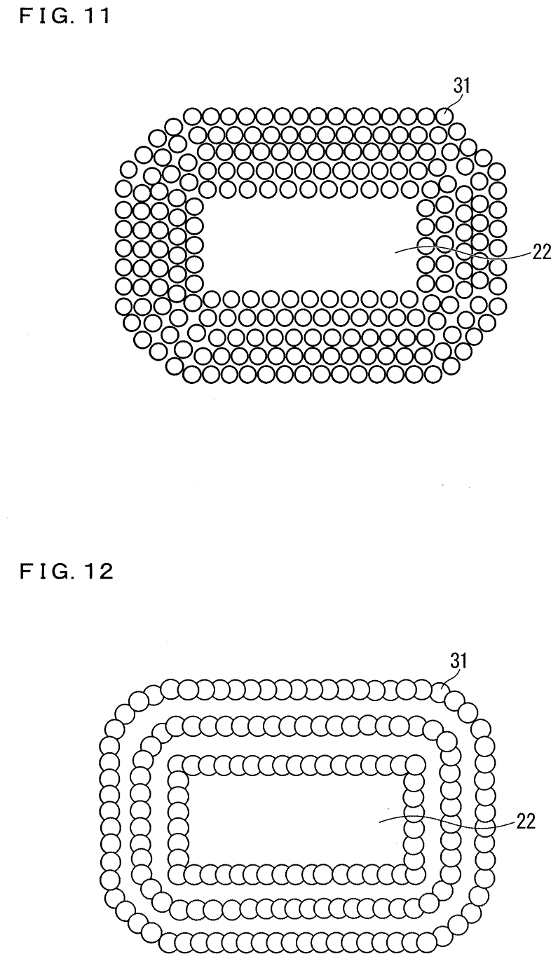

FIG. 11 is a plan view illustrating an arrangement of the processing region 31 according to an embodiment 3. As illustrated in FIG. 11, the second processing region 33 in one of the processing regions 31 and the second processing region 33 in the other one of the processing regions 31 are not overlapped with each other in two processing regions 31 adjacent to each other. That is to say, two adjacent processing regions 31 are not overlapped with each other.

### Effect

According to the embodiment 3, occurrence of a debris at an end portion of the processing region 31 can be suppressed. Accordingly, breakage of the semiconductor device caused by scattering of the debris and maintenance cost of a processing apparatus including the semiconductor device can be reduced.

### Embodiment 4

FIG. 12 is a plan view illustrating an arrangement of the processing region 31 according to an embodiment 4. As illustrated in FIG. 12, the modified portion 21 includes a region in which the adjacent processing regions 31 are overlapped with each other and a region in which the adjacent processing regions 31 are not overlapped with each other.

In the example in FIG. 12, three annular groups of processing regions 31 are formed, and the adjacent processing regions 31 are overlapped with each other in each annular group. An arrangement relationship between two processing regions 31 adjacent to each other is similar to that in the embodiment 1. In the meanwhile, the processing region 31 is not formed between the annular groups, and the adjacent processing regions 31 are not overlapped with each other between the annular groups.

### Effect

According to the embodiment 4, an irradiation area of laser light is reduced, and occurrence of the debris can be suppressed. Accordingly, breakage of the semiconductor device caused by scattering of the debris and maintenance cost of a processing apparatus including the semiconductor device can be reduced.

### Modification Example of Embodiment 4

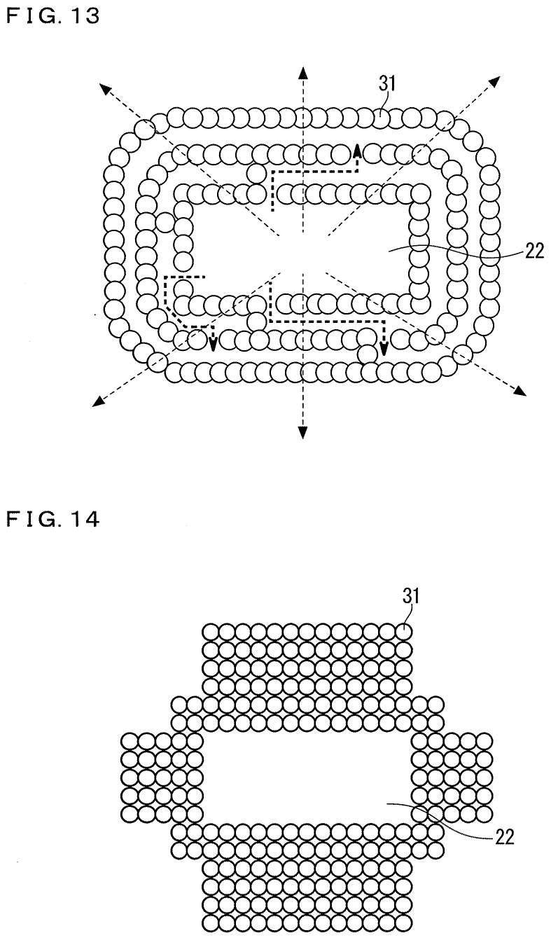

FIG. 13 is a plan view illustrating an arrangement of the processing region 31 according to a modification example of an embodiment 4. As illustrated in FIG. 13, the modified portion 21 includes a plurality of regions in which the adjacent processing regions 31 are overlapped with each other and at least one region in which the adjacent processing regions 31 are not overlapped with each other in a radiation direction (a direction of arrows shown by broken lines in FIG. 13) from a center of the solder bonding region 22. An arrangement relationship between two processing regions 31 adjacent to each other is similar to that in the embodiment 1.

In the example in FIG. 13, three annular groups of processing regions 31 are formed. Each annular group includes a region in which the adjacent processing regions 31 are overlapped with each other and a region in which the adjacent processing regions 31 are not overlapped with each other. However, all of the adjacent processing regions 31 are overlapped with each other in the outermost annular group.

A region in which the adjacent processing regions 31 are overlapped with each other and a region in which the adjacent processing regions 31 are not overlapped with each other are located between the annular groups.

### Effect

According to the modification example of the embodiment 4, an irradiation area of laser light is reduced, and occurrence of the debris can be suppressed. Accordingly, breakage of the semiconductor device caused by scattering of the debris and maintenance cost of a processing apparatus including the semiconductor device can be reduced.

A part of the solder 5 can be leaked and spread in the radiation direction while suppressing leakage and spread of the solder 5 in the radiation direction. Accordingly, stress of the solder 5 occurring after the first external electrode 8 is bonded to the surface electrode solder bonding portion 6 can be reduced, and reliability of the semiconductor device can be further improved.

### Embodiment 5

FIG. 14 is a plan view illustrating an arrangement of the processing region 31 according to an embodiment 5. As illustrated in FIG. 14, the processing regions 31 are linearly disposed. That is to say, an arrangement pattern of the processing regions 31 is made up of only a straight line.

Illustrated in the example in FIG. 14 is a case where the adjacent processing regions 31 are not overlapped with each other. However, the second processing regions in the adjacent processing regions 31 may be overlapped with each other. In this case, an arrangement relationship between two processing regions 31 adjacent to each other is similar to that in the embodiment 1.

### Effect

According to the embodiment 5, the arrangement of the processing regions 31 needs not be a pattern having an R-like shape (refer to FIG. 3, for example). Accordingly, the linear arrangement pattern can be formed even in a device in which an R-shaped arrangement pattern cannot be formed or a device in which it takes a long time to form an arrangement pattern of a part of an R-like shape.

Each embodiment can be arbitrarily combined, or each embodiment can be appropriately varied or omitted within the scope of the present disclosure.

### Appendix

The aspects of the present disclosure are collectively described hereinafter as appendixes.

### Appendix 1

A semiconductor device, comprising:
a semiconductor element;
a surface electrode solder bonding portion provided to a front surface of the semiconductor element;
a solder provided on the surface electrode solder bonding portion; and
a sealing material sealing the semiconductor element and the solder, wherein
the surface electrode solder bonding portion includes a modified portion with an outermost surface oxidized, roughened, and covered by the sealing material and a solder bonding region in which the solder is bonded,
the modified portion includes a plurality of processing regions disposed to surround an outer surrounding portion of the solder bonding region,
each of the processing regions is made up of a first processing region and a second processing region surrounding an outer surrounding portion of the first processing region, and
in two of the processing regions adjacent to each other, the first processing region in one of the processing regions and the first processing region in another one of the processing regions are not overlapped with each other, and the first processing region in one of the processing regions and the second processing region in another one of the processing regions are not overlapped with each other.

### Appendix 2

The semiconductor device according to Appendix 1, wherein
the first processing region has a concave shape concaved more than a surface of the solder bonding region, and
the second processing region has a convex shape protruding more than the surface of the solder bonding region.

### Appendix 3

The semiconductor device according to Appendix 1 or 2, wherein
the modified portion is formed by pulse irradiation with laser light, and
each one of the processing regions is a region processed by a single shot of the pulse irradiation.

### Appendix 4

The semiconductor device according to any one of Appendixes 1 to 3, wherein
the modified portion includes a start point processing region as a start point of processing and a terminal point processing region as a terminal point of processing,
the start point processing region and the terminal point processing region are not overlapped with each other, and
an interval between the start point processing region and the terminal point processing region is larger than an interval between the processing regions other than the start point processing region and the terminal point processing region.

### Appendix 5

The semiconductor device according to Appendix 4, wherein
the one start point processing region and the one terminal point processing region are provided.

### Appendix 6

The semiconductor device according to any one of Appendixes 1 to 3, wherein
in two of the processing regions adjacent to each other, the second processing region in one of the processing regions and the second processing region in another one of the processing regions are not overlapped with each other.

### Appendix 7

The semiconductor device according to any one of Appendixes 1 to 3, wherein
the modified portion includes a region in which the processing regions adjacent to each other are overlapped with each other and a region in which the processing regions adjacent to each other are not overlapped with each other.

### Appendix 8

The semiconductor device according to Appendix 7, wherein
in a radiation direction from a center of the solder bonding region, the modified portion includes a plurality of regions in which the processing regions adjacent to each other are overlapped with each other and at least one region in which the processing regions adjacent to each other are not overlapped with each other.

### Appendix 9

The semiconductor device according to any one of Appendixes 1 to 3, wherein
an arrangement pattern of the processing regions is made up of only a straight line.

### Appendix 10

A method of manufacturing a semiconductor device, comprising the steps of:
(a) forming a semiconductor element;
(b) forming a surface electrode solder bonding portion on a front surface of the semiconductor element;
(c) forming solder on the surface electrode solder bonding portion; and
(d) sealing the semiconductor element and the solder by a sealing material, wherein
in the step (b),
the surface electrode solder bonding portion includes a modified portion with an outermost surface oxidized and roughened and a solder bonding region bonded to the solder,
the modified portion includes a plurality of processing regions disposed to surround an outer surrounding portion of the solder bonding region,
each of the processing regions is made up of a first processing region and a second processing region surrounding an outer surrounding portion of the first processing region,
in two of the processing regions adjacent to each other, the first processing region in one of the processing regions and the first processing region in another one of the processing regions are not overlapped with each other, and the first processing region in one of the processing regions and the second processing region in another one of the processing regions are not overlapped with each other, and
in the step (d), the modified portion is covered by the sealing material.

While the disclosure has been shown and described in detail, the foregoing description is in all aspects illustrative and not restrictive. It is therefore understood that numerous modifications and variations can be devised.

What is claimed is:

1. A semiconductor device, comprising:
a semiconductor element;
a surface electrode solder bonding portion provided to a front surface of the semiconductor element;
a solder provided on the surface electrode solder bonding portion; and
a sealing material sealing the semiconductor element and the solder, wherein the surface electrode solder bonding portion includes a modified portion with an outermost surface oxidized, roughened, and covered by the sealing material and a solder bonding region in which the solder is bonded,
the modified portion includes a plurality of processing regions disposed to surround an outer surrounding portion of the solder bonding region,
each of the processing regions is made up of a first processing region and a second processing region surrounding an outer surrounding portion of the first processing region, and
in two of the processing regions adjacent to each other, the first processing region in one of the processing regions and the first processing region in another one of the processing regions are not overlapped with each other, and the first processing region in one of the processing regions and the second processing region in another one of the processing regions are not overlapped with each other.

2. The semiconductor device according to claim 1, wherein
the first processing region has a concave shape concaved more than a surface of the solder bonding region, and
the second processing region has a convex shape protruding more than the surface of the solder bonding region.

3. The semiconductor device according to claim 1, wherein
the modified portion is formed by pulse irradiation with laser light, and
each one of the processing regions is a region processed by a single shot of the pulse irradiation.

4. The semiconductor device according to claim 1, wherein
the modified portion includes a start point processing region as a start point of processing and a terminal point processing region as a terminal point of processing,
the start point processing region and the terminal point processing region are not overlapped with each other, and
an interval between the start point processing region and the terminal point processing region is larger than an interval between the processing regions other than the start point processing region and the terminal point processing region.

5. The semiconductor device according to claim 4, wherein
the one start point processing region and the one terminal point processing region are provided.

6. The semiconductor device according to claim 1, wherein
in two of the processing regions adjacent to each other, the second processing region in one of the processing regions and the second processing region in another one of the processing regions are not overlapped with each other.

7. The semiconductor device according to claim 1, wherein
the modified portion includes a region in which the processing regions adjacent to each other are overlapped with each other and a region in which the processing regions adjacent to each other are not overlapped with each other.

8. The semiconductor device according to claim 7, wherein
in a radiation direction from a center of the solder bonding region, the modified portion includes a plurality of regions in which the processing regions adjacent to each other are overlapped with each other and at least one region in which the processing regions adjacent to each other are not overlapped with each other.

9. The semiconductor device according to claim 1, wherein
an arrangement pattern of the processing regions is made up of only a straight line.

10. A method of manufacturing a semiconductor device, comprising the steps of:
(a) forming a semiconductor element;
(b) forming a surface electrode solder bonding portion on a front surface of the semiconductor element;
(c) forming solder on the surface electrode solder bonding portion; and
(d) sealing the semiconductor element and the solder by a sealing material, wherein
in the step (b),
the surface electrode solder bonding part includes a modified portion with an outermost surface oxidized and roughened and a solder bonding region bonded to the solder,
the modified portion includes a plurality of processing regions disposed to surround an outer surrounding portion of the solder bonding region,
each of the processing regions is made up of a first processing region and a second processing region surrounding an outer surrounding portion of the first processing region,
in two of the processing regions adjacent to each other, the first processing region in one of the processing regions and the first processing region in another one of the processing regions are not overlapped with each other, and the first processing region in one of the processing regions and the second processing region in another one of the processing regions are not overlapped with each other, and
in the step (d), the modified portion is covered by the sealing material.
